(19) United States
(12) Patent Application Publication
(10) Pub. No.: US 2026/0271452 A1
(43) Pub. Date: Sep. 10, 2026

(54) DOUBLE-SIDED DISPLAY DEVICE

(71) Applicant: Innolux Corporation, Miaoli County (TW)

(72) Inventor: Masahiro Yoshiga, Miaoli County (TW)

(73) Assignee: Innolux Corporation, Miaoli County (TW)

(21) Appl. No.: 19/074,445

(22) Filed: Mar. 10, 2025

(51) Int. Cl. H01L 25/16; H10H 29/45; H10H 29/49; H10K 59/127; H10K 59/128; H10K 59/131; H10K 59/95; H10K 102/00

(52) U.S. Cl. CPC H10H 29/49; H10H 29/45; H10K 59/127; H10K 59/128; H10K 59/131; H10W 90/00; H10K 59/95; H10K 2102/3031

(57) ABSTRACT

A double-sided display device including a plurality of display panels is provided. The double-sided display device has a first side and a second side opposite to each other. One of the plurality of display panels is used to display a first image on the first side, and another of the plurality of display panels is used to display a second image on the second side. Each of the display panels includes a plurality of first signal lines and a plurality of sub-pixels. The plurality of first signal lines respectively extend along a first direction and turn in a zigzag shape with a first period. The plurality of sub-pixels are electrically connected to the plurality of first signal lines and are arranged at a first pitch in the first direction, wherein the first period is an integer multiple of the first pitch.

### BACKGROUND

### Technical Field

The disclosure relates to an electronic device, and more particularly to a double-sided display device.

### Description of Related Art

A double-sided display device is a transparent LED display showing contents on both front side and back side. In detail, the double-sided display device displays the readable different information for both front side and rear side by two panels lamination, in which pixels including a plurality of signal lines are regularly aligned. However, Moiré patterns would be easily generated when there is an offset between the signal lines respectively located in both of the panels.

### SUMMARY

The disclosure provides a double-sided display device, which can reduce the possibility of generating Moiré patterns.

According to some embodiments of the disclosure, the double-sided display device including a plurality of display panels is provided. The double-sided display device has a first side and a second side opposite to each other. One of the plurality of display panels is used to display a first image on the first side, and another of the plurality of display panels is used to display a second image on the second side. Each of the display panels includes a plurality of first signal lines and a plurality of sub-pixels. The plurality of first signal lines respectively extend along a first direction and turn in a zigzag shape with a first period. The plurality of sub-pixels are electrically connected to the plurality of first signal lines and are arranged at a first pitch in the first direction, wherein the first period is an integer multiple of the first pitch.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a partial top view of a double-sided display device according to an embodiment of the disclosure.

FIG. 1B is a partial cross-sectional view along a section line A-A′ of FIG. 1A.

FIG. 1C is a partial top view of a double-sided display device according to another embodiment of the disclosure.

FIGS. 1D and 1E are partial top views of the relationship of signal lines in a double-sided display device according to an embodiment of the disclosure.

FIG. 2A is a partial top view of a pixel region in a first display panel of a double-sided display device according to a first embodiment of the disclosure.

FIG. 2B is a partial top view of a pixel region of a first display panel and a second display panel laminated on each other in the double-sided display device according to the first embodiment of the disclosure.

FIG. 3 is a partial top view of a pixel region in a first display panel of a double-sided display device according to a second embodiment of the disclosure.

FIG. 4 is a partial top view of a pixel region in a first display panel of a double-sided display device according to a third embodiment of the disclosure.

### DESCRIPTION OF THE EMBODIMENTS

The disclosure can be understood by referring to the following detailed description in combination with the accompanying drawings. It should be noted that in order to make it easy for the reader to understand and for the simplicity of the drawings, the multiple drawings in this disclosure only depict a part of the electronic device, and the specific components in the drawings are not drawn according to actual scale. In addition, the number and size of each component in the drawings are only for exemplary purpose, and are not intended to limit the scope of the disclosure.

Throughout the disclosure and the appended claims, certain words are used to refer to specific components. Those skilled in the art should understand that electronic device manufacturers may refer to the same components by different names. The disclosure does not intend to distinguish those components with the same function but different names. In the following description and claims, the terms “including”, “containing”, and “having” are open-ended terms, so they should be interpreted as “include but not limited to . . . ”. Therefore, when the terms “including”, “containing”, and/or “having” are used in the description of this disclosure, they specify the existence of a corresponding feature, region, step, operation, and/or component, but do not exclude the existence of one or more corresponding features, regions, steps, operations, and/or components.

Direction terms mentioned in this specification, such as “up,” “down,” “front,” “back,” “left,” and “right,” merely refer to directions in the accompanying drawings. Therefore, the direction terms used is for illustration, not for limiting this disclosure. In the drawings, each drawing shows the general features of the method, structure, and/or material used in a specific embodiment. However, these drawings should not be construed as defining or limiting the scope or nature of the embodiments. For example, for the sake of clarity, the relative size, thickness, and position of each layer, region, and/or structure may be reduced or enlarged.

When a corresponding member (such as a layer or a region) is described as being “on another member,” it may be directly on another member, or there may be other member therebetween. On the other hand, when a member is described as being “directly on another member,” no member exists therebetween. In addition, when a member is described as being “on another member,” the two have a vertical relationship in the top view direction, and this member may be located above or below the other member, and the vertical relationship depends on the device orientation.

The terms “approximately”, “essentially”, or “substantially” are generally interpreted as within 10% of a given value or range, or as within 5%, 3%, 2%, 1%, or 0.5% of the value or range.

Ordinal numbers in this specification and the claims such as “first” and “second” are used to modify a component, and do not imply or represent that the (or these) component(s) has (or have) any ordinal number, and do not indicate any order between a component and another component, or an order in a manufacturing method. These ordinal numbers are merely used to clearly distinguish a component having a name with another component having the same name. Different terms may be used in the claims and the specification, so that a first member in the specification may be a second member in the claims.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

Electrical connection or coupling described in the disclosure may refer to direct connection or indirect connection. In the case of direct connection, end points of the components on two circuits are directly connected or connected to each other with a conductor segment, and in the case of indirect connection, there are transistors, diodes, capacitors, inductors, other suitable components, or a combination of the above components between the end points of the components on the two circuits, but the disclosure is not limited thereto.

In the disclosure, a thickness, a length, and a width may be measured using an optical microscope, and the thickness may be measured using a cross-sectional image in an electronic microscope. However, the disclosure is not limited thereto. In addition, any two values or directions used for comparison may have certain errors. If a first direction is perpendicular to a second direction, an angle between the first direction and the second direction may be between 80 degrees and 100 degrees. If the first direction is parallel to the second direction, the angle between the first direction and the second direction may be between 0 degrees and 10 degrees.

It should be noted that the following embodiments can replace, reorganize, or mix the technical features in several different embodiments to complete other embodiments without departing from the spirit of the present invention or causing any conflict.

The electronic device in the disclosure could include a detection device, a display device, an antenna device, a light-emitting touch device, a tiled device, a device with other suitable functions, or a combination of devices with the above functions, but the disclosure is not limited thereto. The electronic devices could include rollable electronic devices or flexible electronic devices, but the disclosure is not limited thereto. The electronic device could include liquid crystal, light emitting diode (LED), quantum dot (QD), fluorescence, phosphorescence, other suitable display media or a combination thereof. The light emitting diode could include organic light emitting diode (OLED), micro light emitting diode (micro-LED), sub-millimeter light emitting diode (mini-LED) or quantum dots light emitting diode (QDLED), but the disclosure is not limited thereto. It should be noted that the electronic device could be any of the above-mentioned arrangements and combinations, but the disclosure is not limited thereto. In addition, the shape of the electronic device could be a rectangular shape, a circular shape, a polygonal shape, a shape with curved edges, or other suitable shapes. The display device could have peripheral systems such as drive systems, control systems, light source systems, shelf systems, and so on, so as to support the display devices or the tiled devices. It should be noted that the electronic device could be any of the above-mentioned arrangements and combinations, but the disclosure is not limited thereto. The electronic device may include a plurality of components, in which at least two components may be assembled to form a composite. In the following embodiments, a sensing device will be used as the electronic device to illustrate the disclosure, but the disclosure is not limited thereto.

Reference will now be made in detail to the exemplary embodiments of the disclosure and the same reference numbers are used in the drawings and descriptions to refer to the same or similar parts.

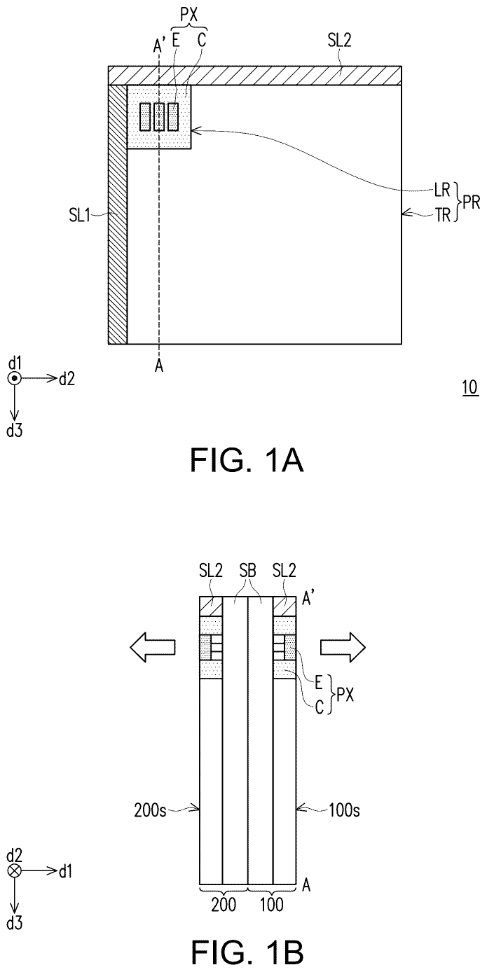

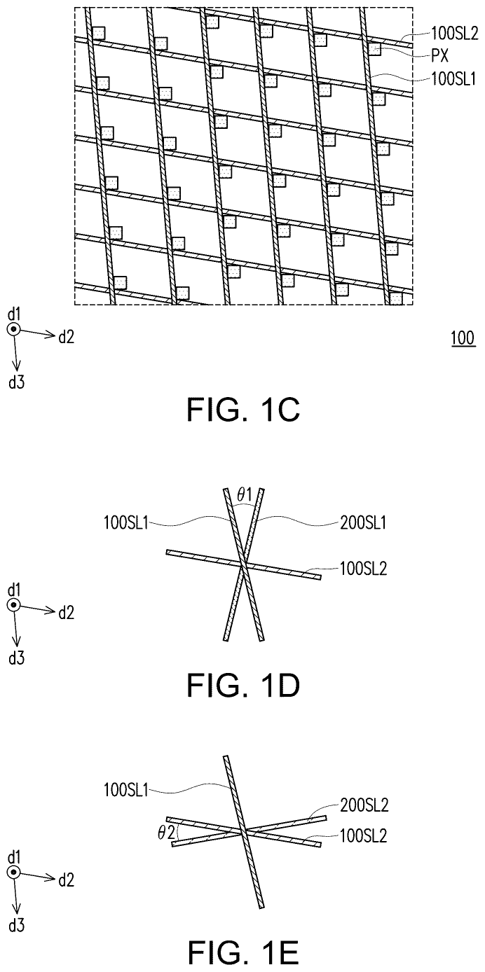

FIG. 1A is a partial top view of a double-sided display device according to an embodiment of the disclosure, and FIG. 1B is a partial cross-sectional view along a section line A-A′ of FIG. 1A.

Referring to FIG. 1A and FIG. 1B, which show a double-sided display device 10 including a first display panel 100 and a second display panel 200. The double-sided display device 10 can be applied to a tablet computer and/or a public information display (PID), but the disclosure is not limited thereto. The first display panel 100 has a first display surface 100s emitting light in a direction d1, and the second display panel 200 has a second display surface 200s emitting light in a direction opposite to the direction d1. From another perspective, the first display panel 100 is used to display a first image on the first side 100s, and the second display panel 200 is used to display a second image on the second side 200s. In the present embodiment, the first display panel 100 and the second display panel 200 include a substrate SB, a plurality of first signal lines SL1, a plurality of second signal lines SL2, and a plurality of sub-pixels PX, but the disclosure is not limited thereto.

A material of the substrate SB can include a hard material, a soft material or a combination thereof. For example, the material of the substrate SB can include glass, quartz, sapphire, polymethyl methacrylate (PMMA), polycarbonate (PC), polyimide (PI), polyethylene terephthalate (PET), other suitable materials or a combination thereof, but the disclosure is not limited thereto.

The plurality of first signal lines SL1 are disposed on the substrate SB. In the present embodiment, the plurality of first signal lines SL1 can include scan lines, data lines, power lines, other suitable signal lines or a combination thereof, but the disclosure is not limited thereto. The plurality of first signal lines SL1 extend in a direction d3, wherein the direction d3 could be orthogonal to the direction d1.

The plurality of second signal lines SL2 are disposed on the substrate SB. In the present embodiment, the plurality of second signal lines SL2 can also include scan lines, data lines, power lines, other suitable signal lines or a combination thereof, and the plurality of second signal lines SL2 and the plurality of first signal lines SL1 have different functions, but the disclosure is not limited thereto. The plurality of second signal lines SL2 extend in a direction d2, wherein the direction d2 could be orthogonal to the direction d3 and the direction d1.

The plurality of sub-pixels PX are disposed on the substrate SB. In the present embodiment, each of the plurality of sub-pixels PX is disposed in a corresponding region defined by the plurality of first signal lines SL1 and the plurality of second signal lines SL2. In detail, two first signal lines SL1 and two second signal lines SL2 intersecting each other can define a pixel region PR, and the plurality of sub-pixels PX are respectively disposed in the corresponding pixel regions PR. In the present embodiment, each of the plurality of sub-pixels PX is electrically connected to the corresponding first signal line SL1 and/or the corresponding second signal line SL2.

In the present embodiment, each of the plurality of pixel regions PR includes a light emitting region LR and a transparent region TR, and the transparent region TR is adjacent to the light emitting region LR.

The light emitting region LR can include an electronic unit E and a circuit layer C. The electronic unit E includes a micro light emitting diode (micro-LED), but the disclosure is not limited thereto. In other embodiments, the electronic unit E can include an organic light emitting diode (OLED), a mini light emitting diode (mini-LED), other suitable light emitting elements or a combination thereof. The circuit layer C can include a plurality of transistors, a plurality of capacitors and/or a plurality of electrodes. For example, the circuit layer C can include a driving transistor, a switching transistor, a reset transistor, a light emitting transistor, and corresponding capacitors, but the disclosure is not limited thereto.

The transparent region TR can include a suitable transparent material, but the disclosure is not limited thereto. In other embodiments, the transparent region T can be switched to a transparent state by applying the corresponding bias voltage. From another perspective, the region other than a region where the sub-pixel PX is disposed can be the transparent region TR. Taking the first display panel 100 as an example, in the transparent region TR, a screen or an object on one side of the first display panel 100 can be seen from the other side, but the disclosure is not limited thereto. In the present embodiment, an area of the transparent region TR is greater than an area of the light emitting region LR.

In the present embodiment, the double-sided display device 10 can further include an adhesive layer (not shown). The adhesive layer is disposed between one of the plurality of display panels and another of the plurality of display panels. In other words, the adhesive layer can be disposed between the first display panel 100 and the second display panel 200.

FIG. 1C is a partial top view of a double-sided display device according to another embodiment of the disclosure, and FIGS. 1D and 1E are partial top views of the relationship of signal lines in a double-sided display device according to an embodiment of the disclosure.

Referring to FIG. 1C, in the present embodiment, taking the first display panel 100 as an example, the plurality of first signal lines 100SL1 are data lines, and the plurality of second signal lines 100SL2 are scan lines. However, the disclosure is not limited thereto. In the present embodiment, the direction d2 and the direction d3 are staggered but not orthogonal to each other.

Referring to FIG. 1D, when the double-sided display device 10 is viewed from a viewing angle of direction d1, the first signal line 100SL1 in the first display panel 100 and a first signal line 200SL1 in the second display panel 200 are not parallel to each other. In the present embodiment, an included angle θ1 between the first signal line 100SL1 in the first display panel 100 and the first signal line 200SL1 in the second display panel 200 can be greater than or equal to 10 degrees. In addition, an included angle between the second signal line 100SL2 in the first display panel 100 and the first signal line 200SL1 in the second display panel 200 can also be greater than or equal to 10 degrees.

Similarly, referring to FIG. 1E, when the double-sided display device 10 is viewed from the viewing angle of direction d1, the second signal line 100SL2 in the first display panel 100 and a second signal line 200SL2 in the second display panel 200 are not parallel to each other. In the present embodiment, an included angle θ2 between the second signal line 100SL2 in the first display panel 100 and the second signal line 200SL2 in the second display panel 200 can be greater than or equal to 10 degrees. In addition, an included angle between the first signal line 100SL1 in the first display panel 100 and the second signal line 200SL2 in the second display panel 200 can also be greater than or equal to 10 degrees.

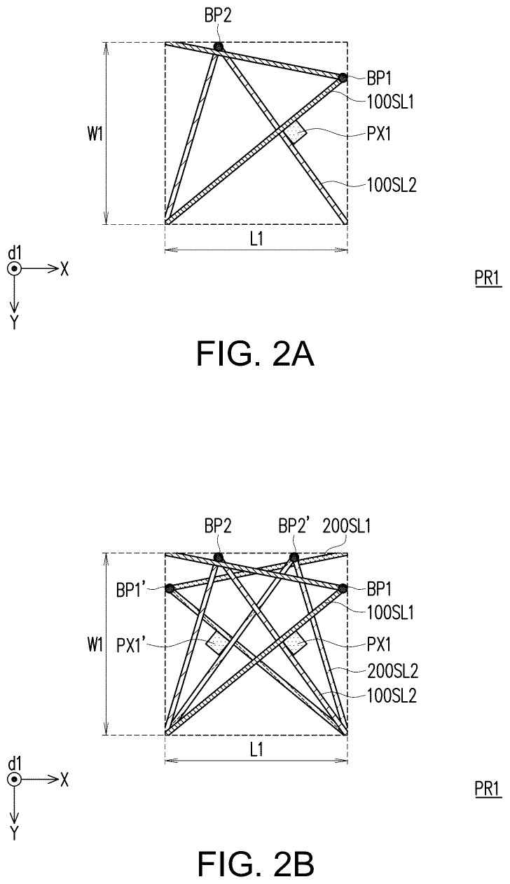

FIG. 2A is a partial top view of a pixel region in a first display panel of a double-sided display device according to a first embodiment of the disclosure, and FIG. 2B is a partial top view of a pixel region of a first display panel and a second display panel laminated on each other in the double-sided display device according to the first embodiment of the disclosure. It should be noted that the embodiment of FIGS. 2A and 2B could respectively use the reference numbers and portions of the content of the above embodiment of FIG. 1A and/or FIG. 1B, wherein the same or similar reference numbers are used to represent the same or similar elements, and descriptions of the same technical contents are omitted.

Referring to FIG. 2A, taking the first display panel 100 as an example, in the present embodiment, each of the plurality of first signal lines 100SL1 includes a first bend point BP1, and each of the plurality of second signal lines 100SL2 includes a second bend point BP2, wherein the first bend point BP1 and the second bend point BP2 can be end points where an extending direction of the first signal line 100SL1 and an extending direction of the second signal line 100SL2 are respectively changed.

In the present embodiment, a pixel region PR1 is defined by one period of the first signal line 100SL1 in a direction Y and one period of the second signal line 100SL2 in a direction X. In detail, a region surrounded by a virtual frame shown in FIG. 2A is the pixel region PR1, which is a minimum area that can include one period of the first signal line 100SL1 in the direction Y and one period of the second signal line 100SL2 in the direction X. Therefore, one pixel region PR1 includes one first signal line 100SL1 and one second signal line 100SL2, but the disclosure is not limited thereto. The sub-pixel PX1 is disposed in a region close to an intersection of the first signal line 100SL1 and the second signal line 100SL2, and is electrically connected to the first signal line 100SL1 and/or the second signal line 100SL2.

In some embodiments, the pixel region PR1 has a length L1 in the direction X and a width W1 in the direction Y. In the present embodiment, the first bend point BP1 is located on one side of the pixel region PR1, and the second bend point BP2 is located on the other side of the pixel region PR1. The first bend point BP1 and the second bend point BP2 can be respectively regarded as a peak of the first signal line 100SL1 and a peak of the second signal line 100SL2. Based on this, a distance between the first bend point BP1 and one border of the virtual frame in the direction X can be the length L1 of the pixel region PR1, and a distance between the second bend point BP2 and one border of the virtual frame in the direction Y can be the width W1 of the pixel region PR1, but the disclosure is not limited thereto.

Referring to FIG. 2B, one period of the first signal line 200SL1 and one period of the second signal line 200SL2 in the second display panel 200 can be projected in the pixel region PR1, wherein the first signal line 200SL1 does not completely overlap with the first signal line 100SL1, and the second signal line 200SL2 does not completely overlap with the second signal line 100SL2. Therefore, the possibility of generated Moire patterns in the double-sided display device 10 could be reduced.

In addition, in the present embodiment, each of the plurality of first signal lines 200SL1 includes a plurality of first bend points BP1′, and each of the plurality of second signal lines 200SL2 includes a plurality of second bend points BP2′, wherein the first bend point BP1′ and the second bend point BP2′ can be end points where an extending direction of the first signal line 200SL1 and an extending direction of the second signal line 200SL2 are respectively changed. The first bend point BP1′ is located on one side of the pixel region PR1, and the second bend point BP2′ is located on the other side of the pixel region PR1. Based on this, a distance between the first bend point BP1′ and one border of the virtual frame in the direction X can be the length L1 of the pixel region P1, and a distance between the second bend point BP2′ and one border of the virtual frame in the direction Y can be the width W1 of the pixel region P1. However, the disclosure is not limited thereto. The sub-pixel PX1′ is disposed in a region close to an intersection of the first signal line 200SL1 and the second signal line 200SL2, and is electrically connected to the first signal line 200SL1 and/or the second signal line 200SL2.

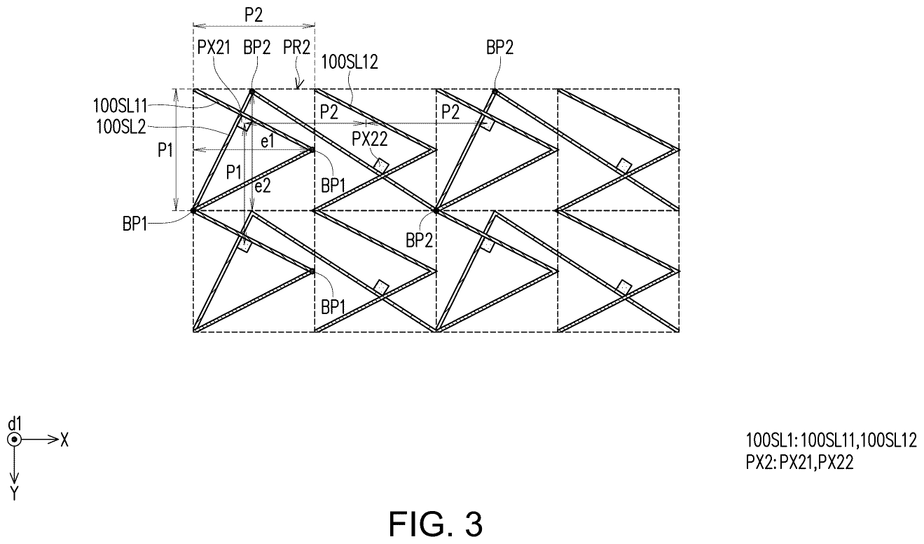

FIG. 3 is a partial top view of a pixel region in a first display panel of a double-sided display device according to a second embodiment of the disclosure. It should be noted that the embodiment of FIG. 3 could use the reference numbers and portions of the content of the above embodiment of FIG. 2A, wherein the same or similar reference numbers are used to represent the same or similar elements, and descriptions of the same technical contents are omitted.

Referring to FIG. 3, taking the first display panel 100 as an example, in the present embodiment, the plurality of first signal lines 100SL1 and the plurality of second signal lines 100SL2 turn in a zigzag shape with a corresponding period. Specifically, each of the plurality of first signal lines 100SL1 and each of the plurality of second signal lines 100SL2 has a wavy structure, wherein each of the plurality of first signal lines 100SL1 includes a plurality of first bend points BP1, and each of the plurality of second signal lines 100SL2 includes a plurality of second bend points BP2. In the present embodiment, a period of the plurality of first signal lines 100SL1 is different from a period of the plurality of second signal lines 100SL2. Specifically, the period of the plurality of first signal lines 100SL1 is approximately half of the period of the plurality of second signal lines 100SL2, but the disclosure is not limited thereto.

In the present embodiment, a region surrounded by a virtual frame shown in FIG. 3 is a pixel region PR2. In some embodiments, two pixel regions PR2 arranged in the direction X can include a minimum area of one period of the second signal line 100SL2 in the direction X, and one pixel region PR2 arranged in the direction Y can include a minimum area of one period of the first signal line 100SL1 in the direction Y. Therefore, the two pixel regions PR2 arranged in the direction X can include two first signal lines 100SL1 and one second signal line 100SL2, but the disclosure is not limited thereto. The sub-pixel PX2 is disposed in a region close to an intersection of the first signal line 100SL1 and the second signal line 100SL2, and is electrically connected to the first signal line 100SL1 and/or the second signal line 100SL2. In the present embodiment, the two pixel regions PR2 respectively include two intersections of the first signal line 100SL1 and the second signal line 100SL2. In other words, the two pixel regions PR2 respectively include two sub-pixels PX2, which are respectively a sub-pixel PX21 and a sub-pixel PX22. The sub-pixel PX21 is disposed in a region close to an intersection of the first signal line 100SL11 and the second signal line 100SL2, and the sub-pixel PX22 is disposed in a region close to an intersection of the first signal line 100SL12 and the second signal line 100SL2.

In the present embodiment, the plurality of pixel regions PR2 are arranged at a pitch P1 in the direction Y. It is worth noting that the pitch P1 can be defined by a pitch in the direction Y between two adjacent sub-pixels PX21 (or two adjacent sub-pixels PX22) at the same position. In some embodiments, the period of the first signal line 100SL1 is an integer multiple of the pitch P1. In the present embodiment, the period of the first signal line 100SL1 is one time the pitch P1, but the disclosure is not limited thereto.

In the present embodiment, the plurality of pixel regions PR2 are arranged at a pitch P2 in the direction X. It is worth noting that the pitch P2 can be defined by half of the pitch in the direction X between two adjacent sub-pixels PX21 (or two adjacent sub-pixels PX22) at the same position. In some embodiments, the period of the second signal line 100SL2 is an integer multiple of the pitch P2. In the present embodiment, the period of the second signal line 100SL2 is twice the pitch P2, but the disclosure is not limited thereto.

In the present embodiment, a distance e1 between two adjacent first bend points BP1 in the direction X is greater than or equal to half of the pitch P2, and a distance e2 between two adjacent second bend points BP2 in direction Y is greater than or equal to half of the pitch P1. With this design, even if the first signal line 100SL1 and/or the second signal line 100SL2 are offset after the first display panel 100 and the second display panel 200 are laminated, the overlapping area thereof remains constant, which can reduce the possibility of generated Moire patterns in the double-sided display device 10.

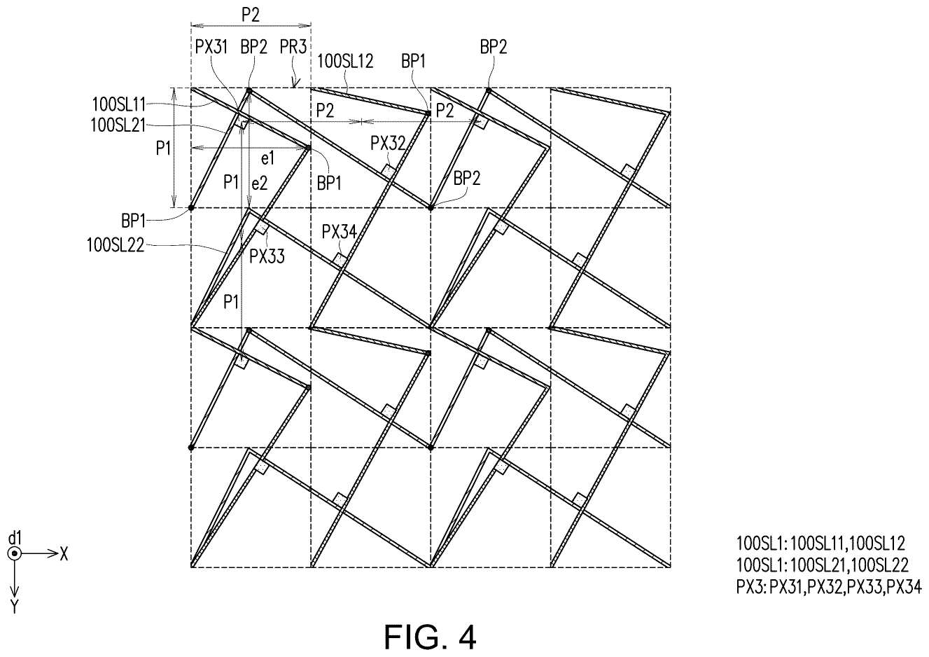

FIG. 4 is a partial top view of a pixel region in a first display panel of a double-sided display device according to a third embodiment of the disclosure. It should be noted that the embodiment of FIG. 4 could use the reference numbers and portions of the content of the above embodiment of FIG. 3, wherein the same or similar reference numbers are used to represent the same or similar elements, and descriptions of the same technical contents are omitted.

Referring to FIG. 4, taking the first display panel 100 as an example, each of the plurality of first signal lines 100SL1 and each of the plurality of second signal lines 100SL2 also has a wavy structure. In the present embodiment, the period of the plurality of first signal lines 100SL1 is substantially equal to the period of the plurality of second signal lines 100SL2, but the disclosure is not limited thereto.

In the present embodiment, a region surrounded by a virtual frame shown in FIG. 4 is a pixel region PR3. In some embodiments, two pixel regions PR3 arranged in the direction X can include a minimum area of one period of the second signal line 100SL2 in the direction X, and two pixel regions PR3 arranged in the direction Y can include a minimum area of one period of the first signal line 100SL1 in the direction Y. Therefore, the 2×2 pixel region composed of the two pixel regions PR3 arranged in the direction X and the two pixel regions PR3 arranged in the direction Y can include two first signal lines 100SL1 and two second signal lines 100SL2. However, the disclosure is not limited thereto.

The sub-pixel PX3 is disposed in a region close to an intersection of the first signal line 100SL1 and the second signal line 100SL2, and is electrically connected to the first signal line 100SL1 and/or the second signal line 100SL2. In the present embodiment, the 2×2 pixel region mentioned above respectively include four intersections of the corresponding first signal line 100SL1 and the corresponding second signal line 100SL2. In other words, the 2×2 pixel region includes four sub-pixels PX3, which are respectively a sub-pixel PX31, a sub-pixel PX32, a sub-pixel PX33 and a sub-pixel PX34. The sub-pixel PX31 is disposed in a region close to an intersection of the first signal line 100SL11 and the second signal line 100SL21, the sub-pixel PX32 is disposed in a region close to an intersection of the first signal line 100SL12 and the second signal line 100SL21, the sub-pixel PX33 is disposed in a region close to an intersection of the first signal line 100SL11 and the second signal line 100SL22, and the sub-pixel PX34 is disposed in a region close to an intersection of the first signal line 100SL12 and the second signal line 100SL22.

In the present embodiment, a plurality of pixel regions PR3 could be arranged at a pitch P1 in the direction Y. It is worth noting that the pitch P1 can be defined by half of a pitch in the direction Y between two adjacent sub-pixels PX31 (or two adjacent sub-pixels PX32; or two adjacent sub-pixels PX33; or two adjacent sub-pixels PX34) at the same position. In some embodiments, the period of the first signal line 100SL1 is an integer multiple of the pitch P1. In the present embodiment, the period of the first signal line 100SL1 is twice the pitch P1, but the disclosure is not limited thereto.

In the present embodiment, a plurality of pixel regions PR3 could be arranged at a pitch P2 in the direction X. It is worth noting that the pitch P2 can be defined by half of a pitch in the direction X between two adjacent sub-pixels PX31 (or two adjacent sub-pixels PX32; or two adjacent sub-pixels PX33; or two adjacent sub-pixels PX34) at the same position. In some embodiments, the period of the second signal line 100SL2 is an integer multiple of the pitch P2. In the present embodiment, the period of the second signal line 100SL2 is twice the pitch P2, but the disclosure is not limited thereto.

In the present embodiment, a distance e1 between two adjacent first bend points BP1 in the direction X is greater than or equal to half of the pitch P2, and a distance e2 between two adjacent second bend points BP2 in direction Y is greater than or equal to half of the pitch P1. With this design, even if the first signal line 100SL1 and/or the second signal line 100SL2 are offset after the first display panel 100 and the second display panel 200 are laminated, the overlapping area thereof remains constant, which can reduce the possibility of generated Moire patterns in the double-sided display device 10.

In summary, in the double-sided display device provided in some embodiments of the disclosure, the signal line turns in a zigzag shape with a first period to have a plurality of bend points, and the distance between two adjacent bend points is greater than or equal to half of the pitch between two adjacent sub-pixels. Based on the above, even if the corresponding signal lines are offset after the plurality of display panels are laminated, the overlapping area remains constant, thereby reducing the possibility of generated Moire patterns in the double-sided display device provided in some embodiments of the disclosure, so as to improve the display quality of double-sided display device provided in some embodiments of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A double-sided display device, having a first side and a second side opposite to each other and including:
a plurality of display panels, one of the plurality of display panels is used to display a first image on the first side, and another of the plurality of display panels is used to display a second image on the second side, wherein each of the display panels includes:
a plurality of first signal lines, respectively extending along a first direction and turn in a zigzag shape with a first period; and
a plurality of sub-pixels, electrically connected to the plurality of first signal lines and are arranged at a first pitch in the first direction,
wherein the first period is an integer multiple of the first pitch.

2. The double-sided display device according to claim 1, further including a light-emitting region and a transparent region, and the transparent region is adjacent to the light-emitting region.

3. The double-sided display device according to claim 2, wherein an area of the transparent region is greater than an area of the light emitting region.

4. The double-sided display device according to claim 1, wherein each of the plurality of first signal lines includes a plurality of first bend points, the plurality of sub-pixels are arranged at a second pitch in a second direction, and the second direction is orthogonal to the first direction.

5. The double-sided display device to claim 4, wherein a distance between the two adjacent first bend points in the second direction is greater than or equal to half of the second pitch.

6. The double-sided display device according to claim 1, wherein the each of the display panels further includes a plurality of second signal lines, each of the plurality of second signal lines extends along a second direction and turns in a zigzag shape with a second period, and the second direction is orthogonal to the first direction, the plurality of sub-pixels are electrically connected to the plurality of second signal lines and are arranged at a second pitch in the second direction, wherein the second period is an integer multiple of the second pitch.

7. The double-sided display device according to claim 6, wherein the first period is different from the second period.

8. The double-sided display device according to claim 6, wherein each of the plurality of second signal lines includes a plurality of second bend points, wherein a distance between two adjacent second bend points in the first direction is greater than or equal to half of the first pitch.

9. The double-sided display device according to claim 1, further including an adhesive layer disposed between the one of the plurality of display panels and the another of the plurality of display panels.

10. The double-sided display device according to claim 1, wherein an included angle between one of the plurality of first signal lines in the first display panel and one of the plurality of first signal lines in the second display panel is greater than or equal to 10 degrees.
